(19) United States
(12) Patent Application Publication
(10) Pub. No.: US 2023/0064521 A1
(43) Pub. Date: Mar. 2, 2023

(54) SEMICONDUCTOR STRUCTURE AND METHOD FOR FORMING SEMICONDUCTOR STRUCTURE

(71) Applicants: Changxin Memory Technologies, Inc., Hefei City (CN); Beijing Superstring Academy of Memory Technology, Beijing (CN)

(72) Inventors: Guangsu Shao, Hefei (CN); Deyuan Xiao, Hefei (CN); Qinghua Han, Hefei (CN); Yunsong Qiu, Hefei (CN); Weiping Bai, Hefei (CN)

(21) Appl. No.: 17/828,462

(22) Filed: May 31, 2022

Related U.S. Application Data
(63) Continuation of application No. PCT/CN2022/077721, filed on Feb. 24, 2022.

(30) Foreign Application Priority Data
Aug. 30, 2021 (CN) 202111007272.0

(51) Int. Cl. H01L 27/108; H01L 29/786; H01L 29/66

(52) U.S. Cl. CPC H01L 27/10873; H01L 27/10814; H01L 29/78642; H01L 27/10855; H01L 29/66742

(57) ABSTRACT

A semiconductor structure and a method for forming a semiconductor structure are provided. The method for forming the semiconductor structure includes the following operations. A base is provided, in which the base includes a substrate, a first semiconductor layer and a second semiconductor layer sequentially formed on one another. A plurality of first isolation structures spaced apart from each other and a plurality of second isolation structures spaced apart from each other are formed in the base. A channel layer is formed in the first semiconductor layer, in which a through hole is provided between the channel layer and each of two first isolation structures adjacent to the channel layer. A gate structure is formed in the through hole.

### CROSS-REFERENCE TO RELATED APPLICATIONS

This is a continuation application of International Patent Application No. PCT/CN2022/077721, filed on Feb. 24, 2022, which claims priority to Chinese Patent Application No. 202111007272.0, filed on Aug. 30, 2021 and entitled “SEMICONDUCTOR STRUCTURE AND METHOD FOR FORMING SEMICONDUCTOR STRUCTURE”. The disclosures of International Patent Application No. PCT/CN2022/077721 and Chinese Patent Application No. 202111007272.0 are incorporated by reference herein in their entireties.

### BACKGROUND

Since a Gate All Around Field Effect Transistor (GAAFET) has better characteristics for controlling a gate, it can achieve better switching characteristics and more effective suppression of short-channel effects, and thus it is considered to be the best candidate as the replacement of the traditional field effect transistors. However, a process for preparing a GAAFET channel is complicated, and random fluctuation of the process is obvious due to the small dimension. Therefore, it is necessary to pay a special attention to the influence of the process fluctuation on the electrical performances of devices and circuits.

### SUMMARY

The disclosure relates to the technical field of semiconductors, and relates, but is not limited, to a semiconductor structure and a method for forming a semiconductor structure.

The disclosure provides a semiconductor structure and a method for forming a semiconductor structure.

In a first aspect, an embodiment of the disclosure provides a method for forming a semiconductor structure, which includes the following operations.

A base is provided, in which the base includes a substrate, a first semiconductor layer and a second semiconductor layer sequentially formed on one another.

A plurality of first isolation structures spaced apart from each other and a plurality of second isolation structures spaced apart from each other are formed in the base, in which a source layer formed in the second semiconductor layer and a drain layer formed in the substrate are provided between any two adjacent first isolation structures of the plurality of first isolation structures, each of the plurality of first isolation structures extends in a first direction, each of the plurality of second isolation structures extends in a second direction, the plurality of first isolation structures penetrate through the first semiconductor layer and the second semiconductor layer and partially extend into the substrate, and the plurality of second isolation structures are arranged in the substrate.

A channel layer is formed in the first semiconductor layer, in which a through hole extending in a same direction as the first direction is provided between the channel layer and each of two first isolation structures adjacent to the channel layer.

A gate structure is formed in the through hole.

In a second aspect, an embodiment of the disclosure further provides a semiconductor structure. The semiconductor structure includes:

a base, in which the base includes a substrate, a first semiconductor layer and a second semiconductor layer sequentially formed on one another;

a plurality of first isolation structures spaced apart from each other and a plurality of second isolation structures spaced apart from each other in the base, in which each the plurality of first isolation structures extends in a first direction, each of the plurality of second isolation structures extends in a second direction, the plurality of first isolation structures penetrate through the first semiconductor layer and the second semiconductor layer and partially extend into the substrate, and the plurality of second isolation structures are arranged in the substrate;

a source layer arranged in the second semiconductor layer;

a drain layer arranged in the substrate;

a channel layer arranged in the first semiconductor layer; and

a gate structure arranged between the channel layer and each of two first isolation structures adjacent to the channel layer and extending in a same direction as the first direction.

### BRIEF DESCRIPTION OF THE DRAWINGS

In the accompanying drawings (which are not necessarily drawn to scale), similar reference numerals may denote similar components in different diagrams. The similar reference numerals having different letter suffixes may denote different examples of the similar components. The accompanying drawings generally illustrate various embodiments discussed in the disclosures by way of example and not by way of limitation.

FIG. 1A is a flowchart of a method for forming a semiconductor structure according to an embodiment of the disclosure;

FIG. 1B to FIG. 1E are schematic diagrams of a forming process of a semiconductor structure according to an embodiment of the disclosure;

FIG. 2A is another flowchart of a method for forming a semiconductor structure according to an embodiment of the disclosure;

FIG. 2B to FIG. 2K are other schematic diagrams of a forming process of a semiconductor structure according to an embodiment of the disclosure;

FIG. 3A is a schematic diagram of a semiconductor structure according to an embodiment of the disclosure;

FIG. 3B is a front view of the structure shown in FIG. 3A;

FIG. 4A is another flowchart of a method for forming a semiconductor structure according to an embodiment of the disclosure; and

FIG. 4B to FIG. 4E are other schematic diagrams of a forming process of a semiconductor structure according to an embodiment of the disclosure.

### DETAILED DESCRIPTION

Exemplary embodiments of the disclosure will be described in more detail below with reference to the accompanying drawings. Although the exemplary embodiments of the disclosure are shown in the accompanying drawings, it should be understood that the disclosure can be implemented in various forms and cannot be limited by specific embodiments illustrated herein. On the contrary, these embodiments are provided to more thoroughly understand the disclosure and to completely convey the scope of the disclosure to those skilled in the art.

In the following description, numerous specific details are set forth in order to provide a more thorough understanding of the disclosure. However, it will be apparent for those skilled in the art that the disclosure can be implemented without one or more of these details. In other examples, in order to avoid confusion with the disclosure, some technical features known in the art are not described. That is, all the features of the actual embodiments are not described here, and the well-known functions and structures are not described in detail.

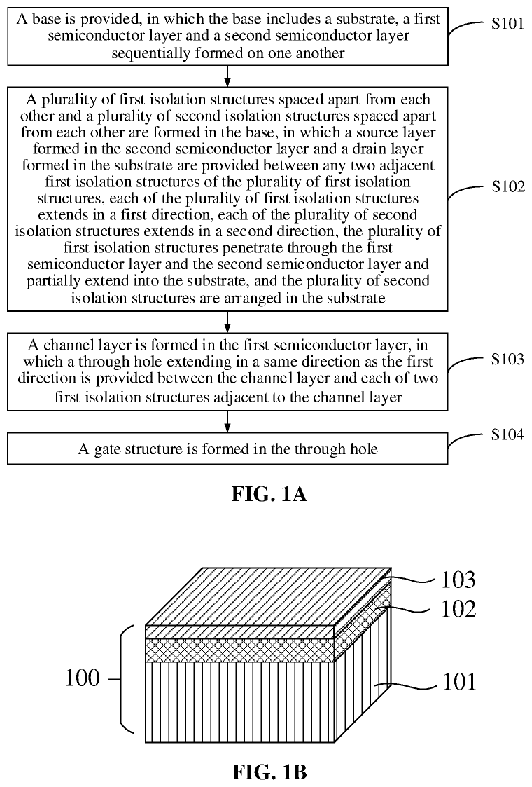

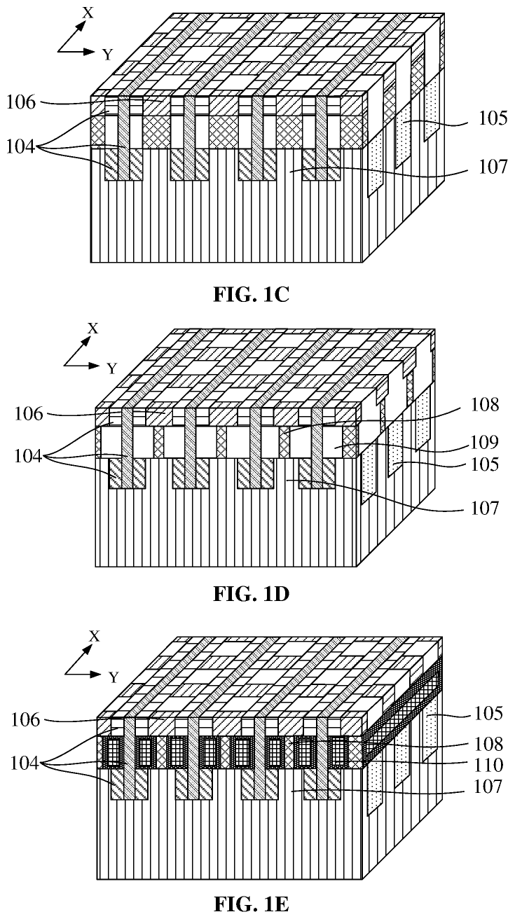

An embodiment of the disclosure provides a method for forming a semiconductor structure. As shown in FIG. 1A, the method includes the following operations.

In S101, a base is provided, in which the base includes a substrate, a first semiconductor layer and a second semiconductor layer sequentially formed on one another.

The substrate may be a silicon substrate, a silicon germanium substrate, or a Silicon On Insulator (SOI) substrate, and may also be a silicon nitride substrate or other suitable substrates.

A material of the first semiconductor layer may be silicon (Si), germanium (Ge), or silicon germanium (GeSi), silicon carbide (SiC); and may also be Silicon On Insulator (SOI) or Germanium on Insulator (GOI); or may also be other materials, for example, III-V group compounds such as gallium arsenide. In terms of a Complementary Metal Oxide Semiconductor (CMOS) process, the cost of a SiGe process is comparable to the cost of a silicon process. However, in terms of the heterojunction technology, the cost of the SiGe process is lower than the cost of a gallium arsenide process.

The second semiconductor layer may be a silicon layer, and may also include other semiconductor elements such as germanium (Ge); or includes semiconductor compounds such as silicon carbide (SiC), gallium arsenide (GaAs), gallium phosphide (GaP), indium phosphide (InP), indium arsenide (InAs), or indium antimonide (InSb); or includes other semiconductor alloys such as silicon germanium (SiGe), gallium arsenide phosphide (GaAsP), indium aluminum arsenide (AlInAs), gallium aluminum arsenide (AlGaAs), indium gallium arsenide (GaInAs), indium gallium phosphide (GaInP), and/or indium gallium arsenide phosphide (GaInAsP) or a combination thereof.

In some embodiments, the first semiconductor layer and the second semiconductor layer may be formed through epitaxy. An epitaxial growth method may adopt Molecular Beam Epitaxy (MBE), a combination of ultralow pressure chemical vapor deposition and ultrahigh vacuum technology (Ultrahigh Vacuum Chemical Vapor Deposition, UHV/CVD), Ultra Violet Chemical Vapor Deposition (UV/CVD), Atmospheric Pressure Chemical Vapor Deposition (APCVD) and Rapid Thermal Chemical Vapor Deposition (RT-CVD), or the like. These technologies have the advantage that they can grow an epitaxial layer at a low temperature (from 300 degrees Celsius (° C.) to 700° C.). This capability is not only important for the generation of the doped planes, but also allows the lattice-mismatched materials to be combined with each other in a coherent manner. In the SiGe alloy, since the carriers in the quantum well composed of silicon (Si) and SiGe have a higher mobility, the mobility of electrons thereof is almost twice that of pure Si. More importantly, when Si and Ge are alloyed, the free-standing alloy has a diamond crystal lattice, and the lattice constant of the alloy is almost linearly dependent between Si and Ge values, with a deviation of about 4.17% at room temperature. When such a SiGe layer is epitaxially grown on a substrate (such as a Si substrate) with the same lattice constant, a growing layer attempts to modify its in-plane lattice constant, in order to form a coherent crystal plane with the substrate layer.

In S102, a plurality of first isolation structures spaced apart from each other and a plurality of second isolation structures spaced apart from each other are formed in the base, in which a source layer formed in the second semiconductor layer and a drain layer formed in the substrate are provided between any two adjacent first isolation structures of the plurality of the first isolation structures, each of the plurality of first isolation structures extends in a first direction, each of the plurality of second isolation structures extends in a second direction, the plurality of first isolation structures penetrate through the first semiconductor layer and the second semiconductor layer and partially extend into the substrate, and the plurality of second isolation structures are arranged in the substrate.

Herein, in a direction of a top surface and a bottom surface of the base (i.e., a plane on which the base is located), the two directions that intersect with each other (e.g., the two directions are perpendicular to each other) are the first direction and the second direction. For example, the first direction is defined as the X-axis direction, and the second direction is defined as the Y-axis direction. The drain layer and the source layer have opposite conductive types.

In S103, a channel layer is formed in the first semiconductor layer, in which a through hole extending in a same direction as the first direction is provided between the channel layer and each of two first isolation structures adjacent to the channel layer.

Herein, the channel layer is arranged between the drain layer and the source layer.

In S104, a gate structure is formed in the through hole.

Herein, the first isolation structure is configured to isolate the gate structures from each other. The gate structure may include a gate oxide layer and a conductive material on a surface of the gate oxide layer. The gate oxide layer may serve as a dielectric layer to realize electric isolation between the gate structure and the base. The gate oxide layer may be formed through high temperature oxidation, and the temperature for the high temperature oxidation process may be comprised between 900° C. and 1200° C. A material of the gate oxide layer may be silicon oxide, silicon nitride, silicon oxynitride, Oxide/Nitride/Oxide (ONO), or a high-k material with a higher dielectric constant than that of the silicon oxide layer, so that it can effectively prevent boron from polysilicon from diffusing to solve the problem of boron penetration. Meanwhile, a small amount of nitrogen atoms distributed on the interface between the gate oxide layer and the base can also improve characteristics of the interface, thereby enhancing the reliability of the gate oxide layer, and reducing the leakage current. For example, the high-k material may have a dielectric constant comprised between about 10 and 25, and may include, for example, hafnium oxide (HfO₂), aluminum oxide (Al₂O₃), hafnium aluminum oxide (HfAlO₃), tantalum oxide (Ta₂O₃), and/or titanium oxide (TiO₂).

In the embodiment of the disclosure, the plurality of first isolation structures and the plurality of second isolation structures are formed in the base, the channel layer is formed in the first semiconductor layer, and the gate structure is formed in the through hole of the channel layer, so that gate self-alignment is realized, and a gate all round structure is formed, thereby improving the gate control capability and the switching speed.

S101 to S104 are illustrated respectively with reference to FIG. 1B to FIG. 1E.

As shown in FIG. 1B, the base 100 includes a substrate 101, a first semiconductor layer 102, and a second semiconductor layer 103 which are sequentially formed on one another.

With reference to FIG. 1B and FIG. 1C, a plurality of first isolation structures 104 spaced apart from each other and a plurality of second isolation structures 105 spaced apart from each other are formed in the base (see the base 100 shown in FIG. 1B). A source layer 106 formed in the second semiconductor layer (see the second semiconductor layer 103 shown in FIG. 1B) and a drain layer 107 formed in the substrate (see the substrate 101 shown in FIG. 1B) are provided between any two adjacent first isolation structures 104. Each first isolation structure 104 extends in the X-axis direction, and each second isolation structure 105 extends in the Y-axis direction. The plurality of first isolation structures 104 penetrate through the first semiconductor layer (see the first semiconductor layer 102 shown in FIG. 1B) and the second semiconductor layer 103, and partially extend into the substrate 101. The plurality of second isolation structures 105 are arranged in the substrate 101.

As shown in FIG. 1D, a channel layer 108 is formed in the first semiconductor layer (see the first semiconductor layer 102 shown in FIG. 1B). A through hole 109 extending in a same direction as the first direction is provided between the channel layer 108 and each of two first isolation structures 104 adjacent to the channel layer.

As shown in FIG. 1E, a gate structure 110 is formed in the through hole 109 (see the through hole 109 shown in FIG. 1D).

On the basis of a method for forming a semiconductor structure provided in FIG. 1A, an embodiment of the disclosure provides a semiconductor structure. As shown in FIG. 1E, the semiconductor structure includes:

a base (see the base 100 shown in FIG. 1B), in which the base includes a substrate (see the substrate 101 shown in FIG. 1B), a first semiconductor layer (see the first semiconductor layer 102 shown in FIG. 1B), and a second semiconductor layer (see the second semiconductor layer 103 shown in FIG. 1B) which are sequentially formed on one another;

a plurality of first isolation structures 104 spaced apart from each other and a plurality of second isolation structures 105 spaced apart from each other in the base 100, in which each first isolation structure 104 extends in a first direction, each second isolation structure 105 extends in a second direction, the plurality of first isolation structures 104 penetrate through the first semiconductor layer 102 and the second semiconductor layer 103 and partially extend into the substrate 101, and the plurality of second isolation structures 105 are arranged in the substrate 101;

a source layer 106 arranged in the second semiconductor layer 103;

a drain layer 107 arranged in the substrate 101;

a channel layer 108 arranged in the first semiconductor layer 102; and

a gate structure 110 arranged between the channel layer 108 and each of two first isolation structures 104 adjacent to the channel layer and extending in a same direction as the first direction.

In some embodiments, the substrate is a silicon substrate, the first semiconductor layer is a silicon germanium layer, and the second semiconductor layer is a silicon layer. The carriers in the silicon germanium layer have a higher mobility, and the electron mobility thereof is twice that of the pure silicon layer.

In some embodiments, the gate structure includes a gate oxide layer, and a conductive material on a surface of the gate oxide layer.

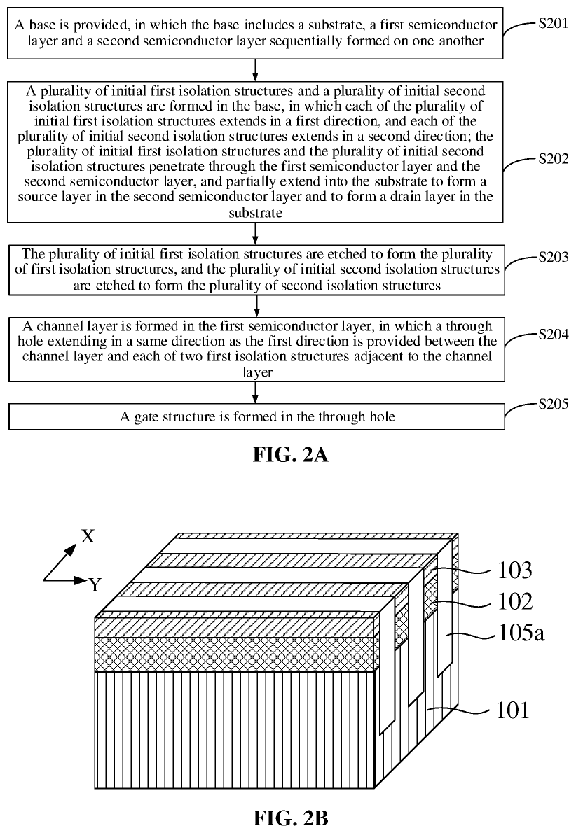

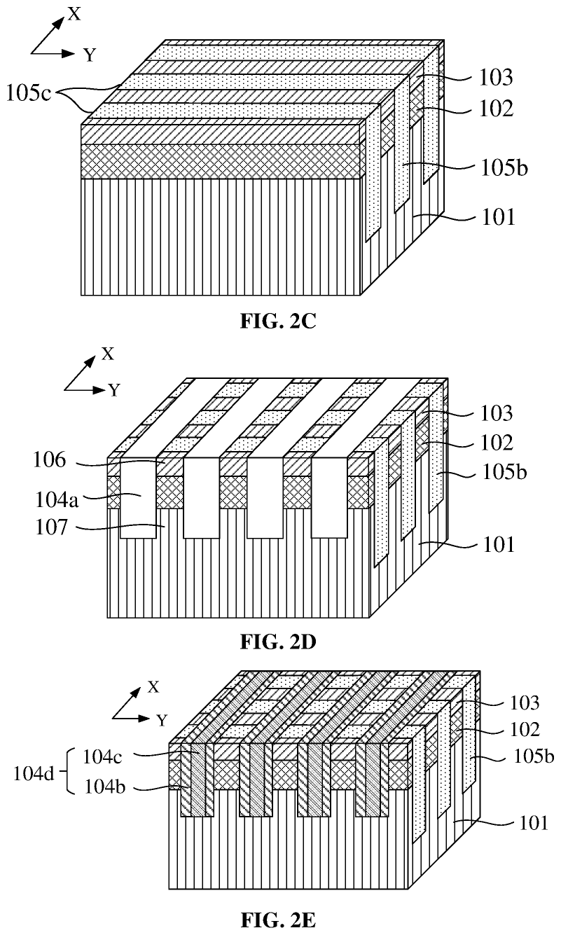

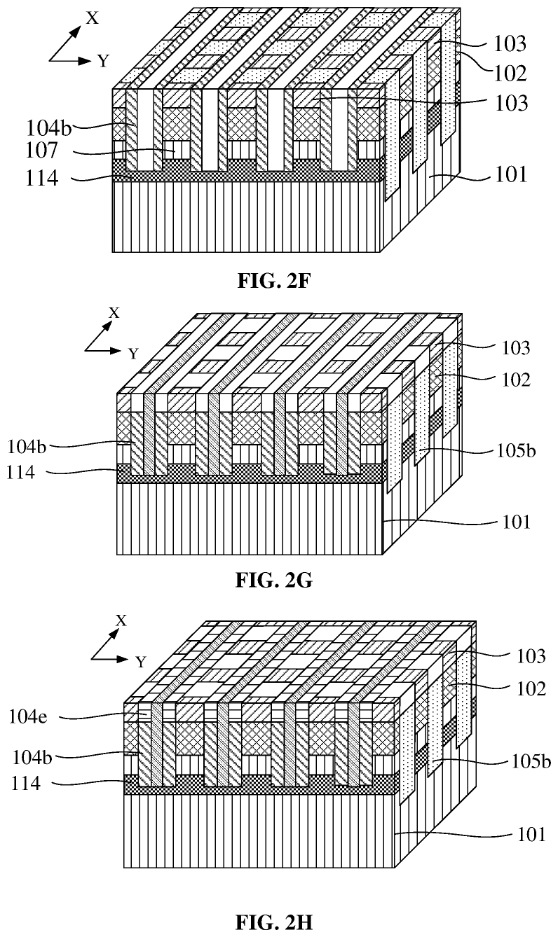

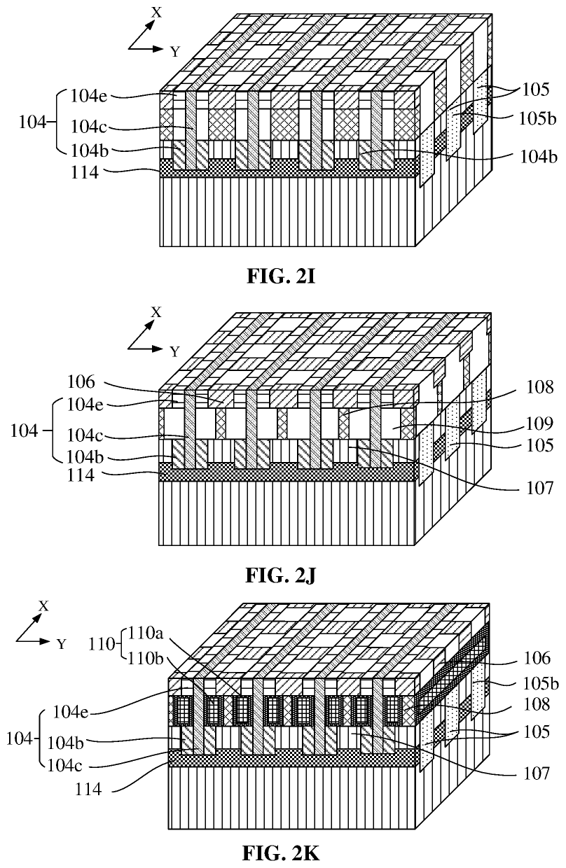

An embodiment of the disclosure further provides a method for forming a semiconductor structure. As shown in FIG. 2A, the method includes the following operations.

In S201, a base is provided, in which the base includes a substrate, a first semiconductor layer and a second semiconductor layer sequentially formed on one another.

In S202, a plurality of initial first isolation structures and a plurality of initial second isolation structures are formed in the base, in which each of the plurality of initial first isolation structures extends in a first direction, and each of the plurality of initial second isolation structures extends in a second direction, and in which the plurality of initial first isolation structures and the plurality of initial second isolation structures penetrate through the first semiconductor layer and the second semiconductor layer, and partially extend into the substrate to form a source layer in the second semiconductor layer and to form a drain layer in the substrate.

In S203, the plurality of initial first isolation structures are etched to form the plurality of first isolation structures, and the plurality of initial second isolation structures are etched to form the plurality of second isolation structures.

In S204, a channel layer is formed in the first semiconductor layer, in which a through hole extending in a same direction as the first direction is provided between the channel layer and each of two first isolation structures adjacent to the channel layer.

In S205, a gate structure is formed in the through hole.

The operation that the plurality of first isolation structures spaced apart from each other and the plurality of second isolation structures spaced apart from each other are formed in the base in the above embodiment may be implemented through S201 to S203.

In some embodiments, S202 may be implemented through S221 and S222. S221 is implemented with reference to FIG. 2B to FIG. 2C, and S222 is implemented with reference to FIG. 2D to FIG. 2E.

In S221, referring to FIG. 2B, a plurality of second isolation structure trenches 105a (in the Y-axis direction) is formed in the base (see the base 100 shown in FIG. 1B). Referring to FIG. 2C, the plurality of second isolation structure trenches (see the second isolation structure trench 105a shown in FIG. 2B) are filled with a first dielectric layer 105b to form the plurality of initial second isolation structures.

In S222, referring to FIG. 2D, after the plurality of initial second isolation structures 105c are formed in the base (as shown in FIG. 2C), a plurality of first isolation structure trenches 104a (in the X-axis direction) are formed in the base. Referring to FIG. 2E, the plurality of first isolation structure trenches (see the first isolation structure trench 104a shown in FIG. 2D) are filled with a second dielectric layer 104b and a third dielectric layer 104c to form the plurality of initial first isolation structures 104d. The plurality of first isolation structure trenches (see the first isolation structure trench 104a shown in FIG. 2D) and the plurality of second isolation structure trenches (see the second isolation structure trench 105a shown in FIG. 2B) penetrate through the first semiconductor layer 102 and the second semiconductor layer 103, and partially extend into the substrate 101.

Herein, the first isolation structure trench and the second isolation structure trench may be formed through a self-aligned shallow trench isolation technology, for example, may be formed through a Self-aligned Double Patterning (SADP) process, or may be formed through a Self-aligned Quadruple Patterning (SAQP) process.

During implementation, firstly, a Sacrifice Layer (generally a CVD material) can be deposited on the surface of the base, and then photolithography and etching are performed to transfer the pattern on the mask to the sacrifice layer. The pattern on the sacrifice layer is also called a “mandrel” or “core”. Atomic Layer Deposition (ALD) is used for depositing a thin film (called a “spacer material”) of a relatively uniform thickness on a surface and a side of the “mandrel”. The deposited spacer material is then etched through a reactive ion etching process, and this operation is known as “etch back”. Due to the geometric effect of a sidewall of the “mandrel”, the material deposited on both sides of the pattern remains to form so-called spacer. The “mandrel” is removed by using a high-selectivity etchant, and only the spacer is remained on the surface of the base. A cycle of the spacer pattern is half of that of a photolithography pattern, so that doubling of the spatial pattern density is realized. Finally, the spacer pattern is transferred to a hard mask of the base through plasma etching.

Herein, the material of the first dielectric layer may be silicon oxide, for example, silicon dioxide, silicon oxynitride or silicon oxide doped with boron and phosphorus, or other suitable materials. The material of the second dielectric layer may be the same as or different from the material of the first dielectric layer. The first dielectric layer may be formed through thermal oxidation, Chemical Vapor Deposition (CVD), Atomic Layer Deposition (ALD), Plasma Enhanced Atomic Layer Deposition (PEALD), Low Pressure Chemical Vapor Deposition (LPCVD) or other suitable processes. The second dielectric layer may be formed through the same process as the first dielectric layer, or may be formed through a different process from the first dielectric layer.

The material of the third dielectric layer may be nitrides, such as silicon nitride, aluminum nitride (AlN), gallium nitride (GaN) and indium nitride (InN), and may be formed through a process such as LPCVD, Atmospheric Pressure Chemical Vapor Deposition (APCVD), or atomic layer deposition.

In some embodiments, the material of the first dielectric layer includes silicon oxide, and the material of the second dielectric layer is the same as the material of the first dielectric layer.

In some embodiments, in S222, the operation that the plurality of first isolation structure trenches are filled with the second dielectric layer and the third dielectric layer to form the plurality of initial first isolation structures may be implemented through S2221 to S2223.

In S2221, the plurality of first isolation structure trenches are filled with the second dielectric layer.

In S2222, the second dielectric layer at a bottom portion of each of the plurality of first isolation structure trenches and on a surface of the second semiconductor layer is removed.

In S2223, the plurality of first isolation structure trenches are filled with the third dielectric layer to form the plurality of initial first isolation structures.

In a practical application, the second dielectric layer at the bottom portion of each of the plurality of first isolation structure trenches may be removed through a dry etching process or a wet etching process. The dry etching process may be a plasma etching process, a reactive ion etching process, or an ion milling process. The second dielectric layer on the surface of the second semiconductor layer may be removed through a Chemical Mechanical Polish (CMP) process.

In some embodiments, the operations S222a and S222b are further included between S2222 and S2223, referring to FIG. 2F. The operations are as follows.

In S222a, metal cobalt is deposited at the bottom portion of each of the plurality of first isolation structure trenches (see the first isolation structure trench 104a shown in FIG. 2D).

In S222b, annealing treatment is performed to form silicide in the substrate 101 to form a buried bit line 114, in which the drain layer 107 is arranged between the channel layer (see the channel layer 108 shown in FIG. 1E) and the buried bit line 114, and the plurality of initial second isolation structures penetrate through the buried bit line 114.

In a practical application, a substance deposited at the bottom portion of the first isolation structure trench is not limited to the metal cobalt, and may also be any one of titanium (Ti), tantalum (Ta), nickel (Ni), tungsten (W), platinum (Pt), and Palladium (Pd). The above metal can be deposited through CVD or ALD.

In a practical application, the annealing treatment allows the metal and the substrate to react with each other to achieve silicidation. Rapid annealing may be performed through rapid thermal annealing at different temperatures according the types of the deposited metal and the substrate. For example, if the metal material is cobalt, the annealing temperature may range from 400° C. to 800° C. The metal silicide formed after silicidation may serve as the buried bit line.

The metal silicide is a substance with a lower resistance than that of polysilicon. With such a substance, the buried bit line has a low resistance. The buried bit line may be formed through a silicidation process. In addition, the buried bit line may be formed through a complete silicidation process. The complete silicidation process is a process for completely silicidating a silicon-containing substance to a desired depth. The buried bit line may be formed by using a near-noble metal such as titanium silicide (TiSiₓ), tungsten silicide (WSiₓ), cobalt silicide (CoSiₓ), and nickel silicide (NiSiₓ), or a metal silicide such as a refractory metal. The metal silicide may be obtained by forming a conductive material through a sputtering process, a CVD process or an ALD process, and then performing the silicidation process. The conductive material may include the near-noble metal or the refractory metal. The buried bit line is subjected to the complete silicidation, so that the resistance of the buried bit line may be reduced.

In some embodiments, S203 may be implemented through S231 to S233, and S231 to S232 are respectively shown in FIG. 2G to FIG. 2I.

In S231, referring to FIG. 2E, the second dielectric layer 104b in the plurality of initial first isolation structures 104d in the second semiconductor layer 103 is etched, and the first dielectric layer 105b in the plurality of initial second isolation structures (see the description regarding to S221) in the second semiconductor layer 103 is etched, so that the structure shown in FIG. 2G can be formed.

In S232, referring to FIG. 2G, the plurality of etched initial first isolation structures (see the initial first isolation structure 104d shown in FIG. 2E) in the second semiconductor layer 103 are filled with a fourth dielectric layer 104e, so that the structure shown in FIG. 2H can be formed.

In S233, referring to FIG. 2H, the second dielectric layer 104b in the plurality of initial first isolation structures (see the initial first isolation structure 104d shown in FIG. 2E) in the first semiconductor layer 102 is etched, and the first dielectric layer 105b in the plurality of initial second isolation structures (see the description regarding to S221) in the first semiconductor layer 102 is etched, so as to form the plurality of first isolation structures 104 and the plurality of second isolation structures 105, so that the structure shown in FIG. 2I can be formed.

Herein, each first isolation structure 104 includes the second dielectric layer 104b, the third dielectric layer 104c, and the fourth dielectric layer 104e.

In some embodiments, a material of the third dielectric layer includes silicon nitride, and a material of the fourth dielectric layer is the same as the material of the third dielectric layer.

In some embodiments, after S233, the method further includes S234, in which, referring to FIG. 2I, a portion of the first semiconductor layer (see the first semiconductor layer 102 shown in FIG. 2H) is etched to form the channel layer 108 as shown in FIG. 2J. The through hole 109 extending in the same direction as the first direction is provided between the channel layer 108 and each of the two first isolation structures 104 adjacent to the channel layer.

During implementation, the first semiconductor layer may be etched along the first direction (i.e., the X-axis direction) through an isotropic quasi-atomic layer etching technology to form the channel layer. The dimension of the channel layer may be controlled, so that the control of the channel by the grate structure can be improved, while improving the switching speed.

S205 is performed. The structure shown in FIG. 2K is formed after the gate structure is formed in the through hole.

On the basis of the structure in FIG. 2K formed by the above method, an embodiment of the disclosure provides a semiconductor structure. The semiconductor structure includes:

a base (see the base 100 shown in FIG. 1B), in which the base includes a substrate (see the substrate 101 shown in FIG. 1B), a first semiconductor layer (see the first semiconductor layer 102 shown in FIG. 1B), and a second semiconductor layer (see the second semiconductor layer 103 shown in FIG. 1B) which are sequentially formed on one another;

a plurality of first isolation structures 104 spaced apart from each other and a plurality of second isolation structures 105 spaced apart from each other in the base, in which each of the plurality of first isolation structures 104 extends in a first direction, each of the plurality of second isolation structures 105 extends in a second direction, the plurality of first isolation structures 104 penetrate through the first semiconductor layer and the second semiconductor layer and partially extend into the substrate, and the plurality of second isolation structures 105 are arranged in the substrate; each first isolation structure 104 includes: a second dielectric layer 104b arranged in the substrate, a fourth dielectric layer 104e arranged in the second semiconductor layer, and a third dielectric layer 104c penetrating through the first semiconductor layer and the second semiconductor layer and partially extending into the substrate; a side wall of the third dielectric layer 104c is in contact with each of the second dielectric layer 104b and the fourth dielectric layer 104e, and each of the plurality of second isolation structures 105 includes a first dielectric layer 105b arranged in the substrate;

a source layer 106 arranged in the second semiconductor layer;

a drain layer 107 arranged in the substrate;

a channel layer 108 arranged in the first semiconductor layer; and

a gate structure 110 arranged between the channel layer 108 and each of two first isolation structures 104 adjacent to the channel layer and extending in a same direction as the first direction.

a buried bit line 114 arranged in the substrate and penetrated by the plurality of second isolation structures 105, in which the drain layer 107 is arranged between the channel layer 108 and the buried bit line 114, and a height of a portion of each of the plurality of first isolation structures 104 extending into the substrate is less than a height of a portion of each of the plurality of second isolation structures 105 arranged in the substrate.

An embodiment of the disclosure further provides a method for forming a semiconductor structure, which includes the following operations.

In S301, as shown in FIG. 1B, a base 100 is provided, in which the base includes a substrate 101, a first semiconductor layer 102 and a second semiconductor layer 103 sequentially formed on one another.

In S302, ion doping is performed on the second semiconductor layer 103 and a portion of the substrate 101, so as to form a drain doped area in the substrate 101, and to form a source doped area in the second semiconductor layer 103.

Herein, the dopant used for ion doping may be an N-type dopant, such as phosphorus (P), arsenic (As), silicon (Si), germanium (Ge), carbon (C), oxygen (O), sulfur (S), selenium (Se), tellurium (Te), or antimony (Sb); and may also be a P-type dopant, such as boron (B), boron fluoride (BF₂), Si, Ge, C, Zinc (Zn), cadmium (Cd), beryllium (Be), magnesium (Mg), or indium (In).

In S303, as shown in FIG. 1C, a plurality of first isolation structures 104 spaced apart from each other and a plurality of second isolation structures 105 spaced apart from each other are formed in the base (see the base 100 shown in FIG. 1B), in which a source layer 106 formed in the second semiconductor layer 103 and a drain layer 107 formed in the substrate 101 are provided between any two adjacent first isolation structures 104 of the plurality of first isolation structures, each of the plurality of first isolation structures 104 extends in a first direction, each of the plurality of second isolation structures 105 extends in a second direction, the plurality of first isolation structures 104 penetrate through the first semiconductor layer 102 and the second semiconductor layer 103 and partially extend into the substrate 101, and the plurality of second isolation structures are arranged in the substrate 101.

In S304, as shown in FIG. 1D, a channel layer 108 is formed in the first semiconductor layer 102, in which a through hole 109 extending in a same direction as the first direction is provided between the channel layer 108 and each of two first isolation structures 104 adjacent to the channel layer.

In S305, as shown in FIG. 1E, a gate structure 110 is formed in the through hole (see the through hole 109 shown in FIG. 1D).

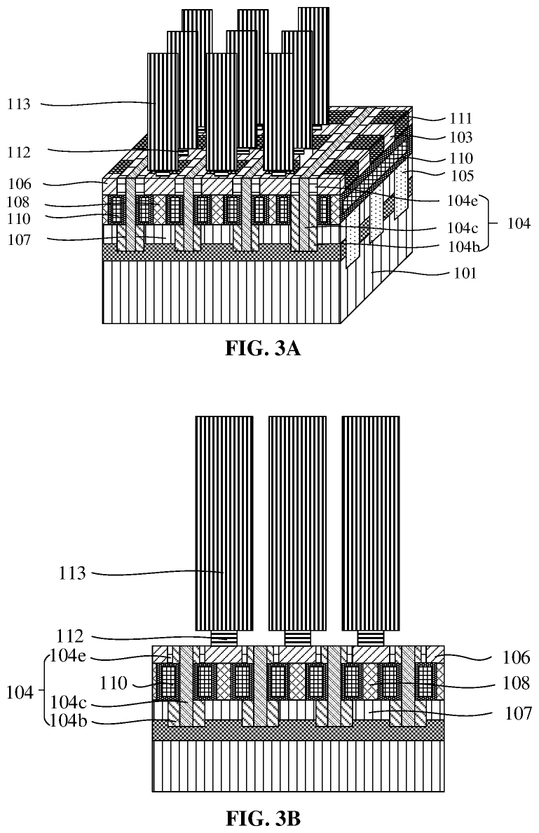

In S306, as shown in FIG. 3A, the second semiconductor layer 103 is filled with a fifth dielectric layer 111. A top surface of the fifth dielectric layer 111 is flush with a top surface of the second semiconductor layer 103.

Herein, a material of the fifth dielectric layer may be nitrides, such as silicon nitride, aluminum nitride (AlN), gallium nitride (GaN), and indium nitride (InN), and the fifth dielectric layer can be formed through a process such as low pressure chemical vapor deposition, atmospheric pressure chemical vapor deposition, or atomic layer deposition.

In S307, as shown in FIG. 3A, a contact node 112 and a capacitor 113 are sequentially formed on each source layer 106.

Herein, the capacitor may be a pillar capacitor, but may not be limited to a cylindrical capacitor. The capacitor may also be a square capacitor or a pillar capacitor of other shapes. The contact node may have a pillar shape or a concave structure.

In some embodiments, S305 may be implemented through S3051 and S3052.

In S3051, a gate oxide layer is formed in the through hole through thermal oxidation.

In S3052, a surface of the gate oxide layer is filled with a conductive material to form the gate structure.

In a practical application, the conductive material may be a metal, such as tungsten (W), or may be a metal nitride, such as titanium nitride.

In some embodiments, the capacitor may include an electrode plate and a dielectric layer. A material of the electrode plate may be titanium nitride (TiN) or aluminum foil, and a material of the dielectric layer may be a composite material of zirconia (ZrO) and Al₂O₃, a ZrO material, a Al₂O₃ material or other materials with a higher dielectric constant than that of SiO₂.

In the embodiment of the disclosure, the first isolation structures and the second isolation structures are formed in the base, the channel layer is formed in the first semiconductor layer, and the gate structure is formed in the through hole of the channel layer, so that a gate all round structure is formed, thereby improving the gate control capability and the switching speed.

The semiconductor structure formed by the above method is shown in FIG. 3A and FIG. 3B. Based on FIG. 3A, an embodiment of the disclosure provides a semiconductor structure, which includes: a base (see the base 100 shown in FIG. 1B), in which the base includes a substrate 101, a first semiconductor layer 102 and a second semiconductor layer 103 sequentially formed on one another;

a plurality of first isolation structures 104 spaced apart from each other and a plurality of second isolation structures 105 spaced apart from each other in the base, in which each of the plurality of first isolation structures 104 extends in a first direction, each of the plurality of second isolation structures 105 extends in a second direction, the plurality of first isolation structures 104 penetrate through the first semiconductor layer 102 and the second semiconductor layer 103 and partially extend into the substrate 101, and the plurality of second isolation structures 105 are arranged in the substrate;

a source layer 106 arranged in the second semiconductor layer 103;

a drain layer 107 arranged in the substrate 101;

a channel layer 108 arranged in the first semiconductor layer 102;

a gate structure 110 arranged between the channel layer 108 and each of two first isolation structures 104 adjacent to the channel layer and extending in a same direction as the first direction.

a fifth dielectric layer 111 arranged in the second semiconductor layer 103, in which a top surface of the fifth dielectric layer 111 is flush with a top surface of the second semiconductor layer 103;

a contact node 112 and a capacitor 113 arranged on each source layer 106.

In some embodiments, as shown in FIG. 3A, the structure further includes a buried bit line 114 arranged in the substrate (see the substrate 101 shown in FIG. 3A) and penetrated by the plurality of second isolation structures 105. The drain layer 107 is arranged between the channel layer 108 and the buried bit line 114. A height of a portion of each of the plurality of first isolation structures 104 extending into the substrate is less than a height of a portion of each of the plurality of second isolation structures 105 arranged in the substrate.

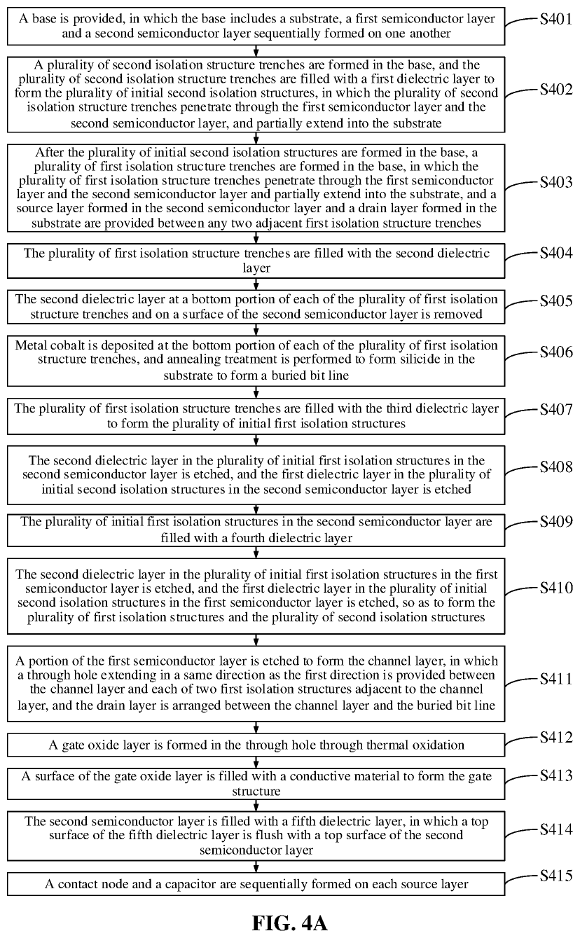

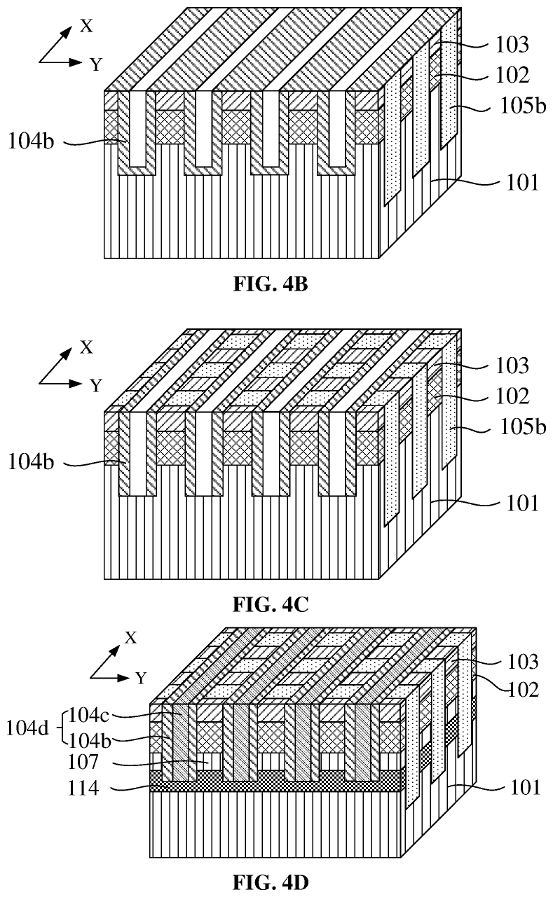

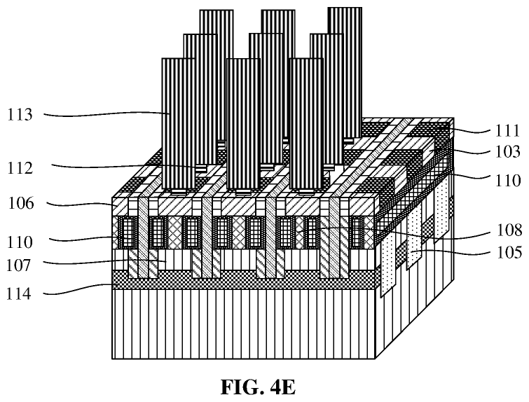

An embodiment of the disclosure further provides a method for forming a semiconductor structure. Referring to FIG. 4A, the method includes the following operations.

In S401, as shown in FIG. 1B, a base 100 is provided, in which the base 100 includes a substrate 101, a first semiconductor layer 102 and a second semiconductor layer 103 sequentially formed on one another.

In S402, referring to FIG. 2B, a plurality of second isolation structure trenches 105a are formed in the base (see the base 100 shown in FIG. 1B); and referring to FIG. 2C, the plurality of second isolation structure trenches (see the second isolation structure trench 105a shown in FIG. 2C) are filled with a first dielectric layer 105b to form the plurality of initial second isolation structures.

The plurality of second isolation structure trenches 105a penetrate through the first semiconductor layer 102 and the second semiconductor layer 103, and partially extend into the substrate 101.

In S403, referring to FIG. 2D, after the plurality of initial second isolation structures are formed in the base, a plurality of first isolation structure trenches 104a are formed in the base, in which the plurality of first isolation structure trenches 104a penetrate through the first semiconductor layer 102 and the second semiconductor layer 103 and partially extend into the substrate 101, and the source layer 106 formed in the second semiconductor layer 103 and the drain layer 107 formed in the substrate 101 are provided between any two adjacent first isolation structure trenches 104a.

In S404, referring to FIG. 2D and FIG. 4B, the plurality of first isolation structure trenches 104a shown in FIG. 2D are filled with the second dielectric layer 104b, so that the structure shown in FIG. 4B can be formed.

In S405, referring to FIG. 4B, the second dielectric layer 104b at a bottom portion of each of the plurality of first isolation structure trenches (see the first isolation structure trench 104a shown in FIG. 2D) and on a surface of the second semiconductor layer 103 is removed, so that the structure shown in FIG. 4C can be formed.

In S406, metal cobalt is deposited at the bottom portion of each of the plurality of first isolation structure trenches (see the first isolation structure trench 104a shown in FIG. 4A); and referring to FIG. 2F, annealing treatment is performed to form silicide in the substrate to form a buried bit line 114.

In S407, referring to FIG. 4D, the plurality of first isolation structure trenches (see the first isolation structure trench 104a shown in FIG. 2D) are filled with the third dielectric layer 104c to form the plurality of initial first isolation structures 104d.

In S408, referring to FIG. 2E, the second dielectric layer 104b in the plurality of initial first isolation structures (see the initial first isolation structure 104d shown in FIG. 4D) in the second semiconductor layer 103 is etched, and the first dielectric layer 105b in the plurality of initial second isolation structures (see the description regarding to S221) in the second semiconductor layer 103 is etched, so that the structure shown in FIG. 2G can be formed.

In S409, referring to FIG. 2G, the plurality of etched initial first isolation structures (see the initial first isolation structure 104d shown in FIG. 4D) in the second semiconductor layer 103 are filled with a fourth dielectric layer 104e, so that the structure shown in FIG. 2H can be formed.

In S410, referring to FIG. 2H, the second dielectric layer 104b in the plurality of initial first isolation structures (see the initial first isolation structure 104d shown in FIG. 4D) in the first semiconductor layer 102 is etched, and the first dielectric layer 105b in the plurality of initial second isolation structures (see the description regarding to S221) in the first semiconductor layer 102 is etched, so as to form the plurality of first isolation structures 104 and the plurality of second isolation structures 105, so that the structure shown in FIG. 2I can be formed.

In S411, referring to FIG. 2I, a portion of the first semiconductor layer (see the first semiconductor layer 102 shown in FIG. 2H) is etched to form the channel layer 108 shown in FIG. 2J, in which a through hole 109 extending in a same direction as the first direction is provided between the channel layer 108 and each of two first isolation structures 104 adjacent to the channel layer, a width of the channel layer 108 in the second direction is less than each of a width of the source layer 106 and a width of the drain layer 107 in the second direction, and the drain layer 107 is arranged between the channel layer 108 and the buried bit line 114.

In S412, referring to FIG. 2K, a gate oxide layer 110a is formed in the through hole (see the through hole 109 shown in FIG. 2J) through thermal oxidation.

In S413, referring to FIG. 2K, a surface of the gate oxide layer 110a is filled with a conductive material 110b to form the gate structure 110.

In S414, referring to FIG. 4E, the second semiconductor layer 103 is filled with a fifth dielectric layer 111, in which a top surface of the fifth dielectric layer 111 is flush with a top surface of the second semiconductor layer 103.

In S415, referring to FIG. 4E, a contact node 112 and a capacitor 113 are sequentially formed on each source layer 106.

The above description of the semiconductor structure embodiment is similar to the description of the above method embodiment, and has beneficial effects similar to that of the method embodiment. The understanding for technical details not disclosed in the semiconductor structure embodiments of the disclosure refer to the description of the method embodiments of the disclosure.

In the several embodiments provided in the disclosure, it should be understood that the disclosed device and method may be implemented in non-target manners. The described device embodiments are merely exemplary. For example, the unit division is merely logical function division and may be other division in an actual implementation. For example, a plurality of units or components may be combined or integrated into another system, or some features may be ignored or not performed. In addition, the displayed or discussed components may be coupled or directly coupled to each other.

The units described above as separate components may or may not be physically separated. Components presented as units may or may not be physical units, that is, may be located in one place or may be distributed over multiple network units. Part or all of these units may be selected according to practical requirements to achieve the objectives of the solutions of the embodiment.

The features disclosed in the several method or structure embodiments provided in the disclosure may be combined with each other arbitrarily without conflict, so as to obtain new method embodiments or structure embodiments.

The above are only some embodiments of the embodiments of the disclosure, but the protection scope of the embodiments of the disclosure is not limited thereto. Any skilled in the art, within the technical scope disclosed by the embodiments of the disclosure, may easily think of variations or replacements, which should be covered within the protection scope of the embodiments of the disclosure. Therefore, the protection scope of the embodiments of the disclosure should be subject to the protection scope of the claims.

1. A method for forming a semiconductor structure, comprising:
providing a base, wherein the base comprises a substrate, a first semiconductor layer and a second semiconductor layer sequentially formed on one another;
forming a plurality of first isolation structures spaced apart from each other and a plurality of second isolation structures spaced apart from each other in the base, wherein a source layer formed in the second semiconductor layer and a drain layer formed in the substrate are provided between any two adjacent first isolation structures of the plurality of first isolation structures, each of the plurality of first isolation structures extends in a first direction, each of the plurality of second isolation structures extends in a second direction, the plurality of first isolation structures penetrate through the first semiconductor layer and the second semiconductor layer and partially extend into the substrate, and the plurality of second isolation structures are arranged in the substrate;
forming a channel layer in the first semiconductor layer, wherein a through hole extending in a same direction as the first direction is provided between the channel layer and each of two first isolation structures adjacent to the channel layer; and
forming a gate structure in the through hole.

2. The method according to claim 1, wherein the method, before forming the plurality of first isolation structures spaced apart from each other and the plurality of second isolation structures spaced apart from each other in the base, further comprises:
performing ion doping on the second semiconductor layer and a portion of the substrate to form a drain doped area in the substrate, and to form a source doped area in the second semiconductor layer.

3. The method according to claim 1, wherein forming the plurality of first isolation structures spaced apart from each other and the plurality of second isolation structures spaced apart from each other in the base comprises:
forming a plurality of initial first isolation structures and a plurality of initial second isolation structures in the base, wherein each of the plurality of initial first isolation structures extends in the first direction, and each of the plurality of initial second isolation structures extends in the second direction, and wherein the plurality of initial first isolation structures and the plurality of initial second isolation structures penetrate through the first semiconductor layer and the second semiconductor layer, and partially extend into the substrate to form the source layer in the second semiconductor layer and to form the drain layer in the substrate; and
etching the plurality of initial first isolation structures to form the plurality of first isolation structures, and etching the plurality of initial second isolation structures to form the plurality of second isolation structures.

4. The method according to claim 3, wherein forming the plurality of initial first isolation structures and the plurality of initial second isolation structures in the base comprises:
forming a plurality of second isolation structure trenches in the base, and filling the plurality of second isolation structure trenches with a first dielectric layer to form the plurality of initial second isolation structures; and
after forming the plurality of initial second isolation structures in the base, forming a plurality of first isolation structure trenches in the base, and filling the plurality of first isolation structure trenches with a second dielectric layer and a third dielectric layer to form the plurality of initial first isolation structures, wherein the plurality of first isolation structure trenches and the plurality of second isolation structure trenches penetrate through the first semiconductor layer and the second semiconductor layer, and partially extend into the substrate.

5. The method according to claim 4, wherein filling the plurality of first isolation structure trenches with the second dielectric layer and the third dielectric layer to form the plurality of initial first isolation structures comprises:
filling the plurality of first isolation structure trenches with the second dielectric layer;
removing the second dielectric layer at a bottom portion of each of the plurality of first isolation structure trenches and on a surface of the second semiconductor layer; and
filing the plurality of first isolation structure trenches with the third dielectric layer to form the plurality of initial first isolation structures.

6. The method according to claim 4, wherein etching the plurality of initial first isolation structures to form the plurality of first isolation structures and etching the plurality of initial second isolation structures to form the plurality of second isolation structures comprises:
etching the second dielectric layer in the plurality of initial first isolation structures in the second semiconductor layer, and etching the first dielectric layer in the plurality of initial second isolation structures in the second semiconductor layer;
filling the plurality of etched initial first isolation structures in the second semiconductor layer with a fourth dielectric layer; and
etching the second dielectric layer in the plurality of initial first isolation structures in the first semiconductor layer, and etching the first dielectric layer in the plurality of initial second isolation structures in the first semiconductor layer to form the plurality of first isolation structures and the plurality of second isolation structures.

7. The method according to claim 6, wherein the method, after etching the second dielectric layer in the plurality of initial first isolation structures in the first semiconductor layer and etching the first dielectric layer in the plurality of initial second isolation structures in the first semiconductor layer, comprises:
etching a portion of the first semiconductor layer to form the channel layer, wherein the through hole extending in the same direction as the first direction is provided between the channel layer and each of the two first isolation structures adjacent to the channel layer, and a width of the channel layer in the second direction is less than each of a width of the source layer and a width of the drain layer in the second direction.

8. The method according to claim 5, wherein the method, after removing the second dielectric layer at the bottom portion of each of the plurality of first isolation structure trenches and on the surface of the second semiconductor layer, and before filing the plurality of first isolation structure trenches with the third dielectric layer, further comprises:
depositing metal cobalt at the bottom portion of each of the plurality of first isolation structure trenches; and
performing an annealing treatment to form silicide in the substrate to form a buried bit line, wherein the drain layer is arranged between the channel layer and the buried bit line, a height of a portion of each of the plurality of first isolation structures extending into the substrate is less than a height of a portion of each of the plurality of second isolation structures arranged in the substrate, and the plurality of second isolation structures penetrate through the buried bit line.

9. The method according to claim 1, wherein forming the gate structure in the through hole comprises:
forming a gate oxide layer in the through hole through thermal oxidation; and
filling a surface of the gate oxide layer with a conductive material to form the gate structure.

10. The method according to claim 9, further comprising:
filling the second semiconductor layer with a fifth dielectric layer, wherein a top surface of the fifth dielectric layer is flush with a top surface of the second semiconductor layer; and
sequentially forming a contact node and a capacitor on the source layer.

11. The method according to claim 6, wherein a material of the first dielectric layer comprises silicon oxide, and a material of the second dielectric layer is the same as the material of the first dielectric layer, and wherein a material of the third dielectric layer comprises silicon nitride, and a material of the fourth dielectric layer is the same as the material of the third dielectric layer.

12. The method according to claim 10, wherein a material of the gate oxide layer comprises silicon oxide, and a material of the fifth dielectric layer comprises silicon nitride.

13. A semiconductor structure, comprising:
a base, wherein the base comprises a substrate, a first semiconductor layer and a second semiconductor layer sequentially formed on one another;
a plurality of first isolation structures spaced apart from each other and a plurality of second isolation structures spaced apart from each other in the base, wherein each of the plurality of first isolation structures extends in a first direction, each of the plurality of second isolation structures extends in a second direction, the plurality of first isolation structures penetrate through the first semiconductor layer and the second semiconductor layer and partially extend into the substrate, and the plurality of second isolation structures are arranged in the substrate;
a source layer arranged in the second semiconductor layer;
a drain layer arranged in the substrate;
a channel layer arranged in the first semiconductor layer; and
a gate structure arranged between the channel layer and each of two first isolation structures adjacent to the channel layer and extending in a same direction as the first direction.

14. The semiconductor structure according to claim 13, wherein each of the plurality of first isolation structures comprises: a second dielectric layer arranged in the substrate, a fourth dielectric layer arranged in the second semiconductor layer, and a third dielectric layer penetrating through the first semiconductor layer and the second semiconductor layer and partially extending into the substrate, and wherein a side wall of the third dielectric layer is in contact with each of the second dielectric layer and the fourth dielectric layer, and each of the plurality of second isolation structures comprises a first dielectric layer arranged in the substrate.

15. The semiconductor structure according to claim 14, further comprising: a buried bit line arranged in the substrate and penetrated by the plurality of second isolation structures, wherein the drain layer is arranged between the channel layer and the buried bit line, and a height of a portion of each of the plurality of first isolation structures extending into the substrate is less than a height of a portion of each of the plurality of second isolation structures arranged in the substrate.

16. The semiconductor structure according to claim 13, wherein the substrate is a silicon substrate, the first semiconductor layer is a silicon germanium layer, and the second semiconductor layer is a silicon layer.

17. The semiconductor structure according to claim 16, wherein the gate structure comprises a gate oxide layer, and a conductive material on a surface of the gate oxide layer.

18. The semiconductor structure according to claim 13, further comprising:
a fifth dielectric layer arranged in the second semiconductor layer, wherein a top surface of the fifth dielectric layer is flush with a top surface of the second semiconductor layer; and
a contact node and a capacitor arranged on the source layer.

19. The semiconductor structure according to claim 14, wherein a material of the first dielectric layer comprises silicon oxide, and a material of the second dielectric layer is the same as the material of the first dielectric layer, and wherein a material of the third dielectric layer comprises silicon nitride, and a material of the fourth dielectric layer is the same as the material of the third dielectric layer.
